(19) United States
(12) Patent Application Publication
(10) Pub. No.: US 2025/0355037 A1
(43) Pub. Date: Nov. 20, 2025

(54) DEVICE AND METHODS FOR MONITORING PARAMETRIC DATA

(71) Applicant: Microchip Technology Incorporated, Chandler, AZ (US)

(72) Inventors: Mazhar Hoque, Gilbert, AZ (US); Alberto Aguilera, Maricopa, AZ (US); Joseph Rascon, Chandler, AZ (US)

(73) Assignee: Microchip Technology Incorporated, Chandler, AZ (US)

(21) Appl. No.: 18/820,718

(22) Filed: Aug. 30, 2024

Related U.S. Application Data
(60) Provisional application No. 63/647,189, filed on May 14, 2024.

(51) Int. Cl. G01R 31/26

(52) U.S. Cl. CPC G01R 31/2642

(57) ABSTRACT

A system for reliability testing may include one or more sockets to receive respective semiconductor devices. A switch driver and a network of switches may control a voltage or current applied to each of the respective semiconductor devices. A measurement system may read signals from the respective semiconductor devices during testing and may calculate parametric values while reliability testing is ongoing.

### PRIORITY

This application claims priority to commonly owned U.S. Patent Application No. 63/647,189 filed May 14, 2024, the entire contents of which are hereby incorporated by reference for all purposes.

### FIELD OF THE INVENTION

The present disclosure relates to a system and method for monitoring parametric data, more specifically to monitoring parametric data in a semiconductor testing environment.

### BACKGROUND

In the field of semiconductor manufacturing and testing, “burn-in” is a common process for detecting failures in a population of semiconductor devices. A burn-in process typically involves electrical stress of a device at elevated or extreme voltages and temperatures. Burn-in is typically performed on devices or device components as they are produced, to detect early failures caused by faults in the manufacturing process or design. Burn-in may be referred to more generally as reliability testing.

Existing reliability testing systems may allow for stress to be applied to one or more semiconductor devices in the form of extreme voltages, temperatures or currents. After semiconductor device stress is completed, semiconductor devices may be removed from the stress environment and tested to determine if the semiconductor device is still functional after stress. Stress may be applied to the devices by placing them in an oven. Use of an oven requires the surrounding circuitry to be tolerant to the extreme temperatures that the device is stressed at, and requires long cable lengths from the semiconductor device within the oven to a voltage or current source outside the oven. Such long cables and circuitry may prevent measurement of lower magnitude of currents and voltages.

Additionally, existing reliability systems may not allow continuous monitoring of semiconductor device parametrics. Testing may only be performed after the semiconductor device is removed from the oven or other stress environment and transported to specialized testing equipment. Significant characterization time and resources may be wasted as, in one of various examples, a semiconductor device may fail during the first hour of reliability testing, but may only be discovered during a post-stress testing operation, which may occur hundreds of hours later.

There is a need for a system which may enable monitoring of semiconductor device parametric data during reliability testing and may enable measurement of low magnitudes of currents and voltages which may detect the onset of failure at an early stage.

### SUMMARY

The examples herein enable a system and method for monitoring parametric data.

According to one aspect, a device includes a circuit board comprising one or more sockets, respective sockets to receive one or more semiconductor devices. The device may include at least one gate switch, a first node of the at least one gate switch coupled to a first node of a respective socket. The device may include at least one drain switch, a first node of the at least one drain switch coupled to a second node of a respective socket. The device may include a high-side switch to selectively couple respective second nodes of the at least one drain switch to a global drain switch. The global drain switch may selectively couple to a first source and a first measurement circuit. The device may include a low-side switch to selectively couple respective second nodes of the one or more gate switches to a global gate switch. The global gate switch may be selectively coupled to a second source and a second measurement circuit. The device may include a switch driver to generate control signals to the at least one drain switch, the at least one gate switch, the high-side switch, the low-side switch, the global gate switch and the global drain switch. The switch driver may configure the at least one drain switch, the at least one gate switch, the high-side switch, the low-side switch, the global gate switch and the global drain. The device may operate to couple a signal from the first source to one of the one or more sockets and to measure one or more parametric values at the second measurement circuit. The device may operate to couple a signal from the second source to one of the one or more sockets and to measure one or more parametric values at the first measurement circuit.

According to one aspect, a system includes a controller coupled to a circuit board, the circuit board including one or more cards comprising one or more sockets. The respective sockets may receive one or more semiconductor devices. The system may include at least one gate switch, a first node of the at least one gate switch coupled to a first node of a respective socket. The system may include at least one drain switch, a first node of the at least one drain switch coupled to a second node of a respective socket. They system may include a high-side switch to selectively couple respective second nodes of the at least one drain switch to a global drain switch, the global drain switch coupled to a first source and a first measurement circuit. The system may include a low-side switch to selectively couple respective second nodes of the one or more gate switches to a global gate switch, the global gate switch coupled to a second source and a second measurement circuit. The system may include a switch driver to generate control signals to the at least one drain switch, the at least one gate switch, the high-side switch, the low-side switch, the global gate switch and the global drain switch. During a reliability testing operation, the controller may instruct the switch driver to couple the first node of one of the received semiconductor devices to a first measurement circuit and to instruct the first measurement circuit to perform a first measurement operation. During a reliability testing operation, the controller may instruct the switch driver to couple a second node of one of the received semiconductor devices to the second measurement circuit and to instruct the second measurement circuit to perform a second measurement operation.

According to one aspect, a method includes steps of: setting an environmental condition at a device under test, applying a voltage or current to one or more nodes of the device under test, coupling one or more nodes of the device under test to a measurement unit, and measuring, at the measurement unit, during a reliability testing operation, one or more parametric data values of the device under test.

### BRIEF DESCRIPTION OF THE DRAWINGS

FIG. 1 illustrates one of various examples of a system for monitoring semiconductor device parametric data during reliability testing

FIG. 2 illustrates another example of a system for monitoring semiconductor device parametric data during a reliability testing operation.

FIG. 3 illustrates a method of monitoring semiconductor device parametric data during a reliability testing operation.

### DETAILED DESCRIPTION

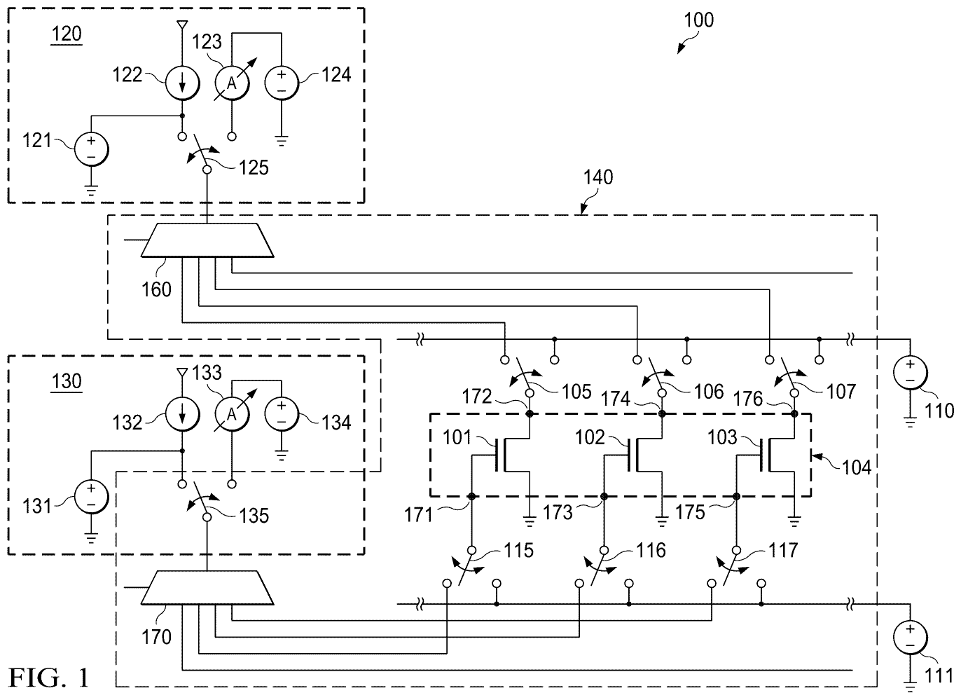

FIG. 1 illustrates one of various examples of a system 100 for monitoring semiconductor device parametric data during reliability testing.

System 100 may include Printed Circuit Board (PCB) 140, a first measurement circuit 120, and a second measurement circuit 130. PCB 140 may include one or more devices-under-test (DUTs). The example illustrated in FIG. 1 includes 3 DUTs, 101, 102, and 103, but this is not intended to be limiting.

DUTs 101, 102 and 103 may be placed in socket 104. Socket 104 may include a single socket to receive all of DUTs 101, 102 and 103, or may include respective sockets for respective DUTs 101, 102 and 103.

In the example illustrated in FIG. 1, first DUT 101 may be a driver comprising a single MOSFET device, but this is not intended to be limiting. In other examples, first DUT 101 may be a semiconductor device of greater complexity than a driver comprising a single MOSFET device.

A first node 171 of socket 104 may couple a gate node of first DUT 101 to first gate switch 115. First gate switch 115 may selectively couple the gate node of first DUT 101 to one of gate stress voltage source 111 and multiplexer 170. Multiplexer 170 may couple the gate node of one of DUTs 101, 102, 103 to second measurement circuit 130.

A second node 172 of socket 104 may couple a drain node of first DUT 101 to first drain switch 105. First drain switch 105 may selectively couple the drain node of first DUT 101 to one of drain stress voltage source 110 and multiplexer 160. Multiplexer 160 may couple one of DUTs 101, 102, 103 to first measurement circuit 120.

In the example illustrated in FIG. 1, second DUT 102 may be a driver comprising a single MOSFET device, but this is not intended to be limiting. In other examples, second DUT 102 may be a semiconductor device of greater complexity than a driver comprising a single MOSFET device.

A third node 173 of socket 104 may couple a gate node of second DUT 102 to second gate switch 116. Second gate switch 116 may selectively couple the gate node of second DUT 102 to one of gate stress voltage source 111 and multiplexer 170.

A fourth node 174 of socket 104 may couple a drain node of second DUT 102 to second drain switch 106. Second drain switch 106 may selectively couple the drain node of second DUT 102 to one of drain stress voltage source 110 and multiplexer 160.

A fifth node 175 of socket 104 may couple a gate node of third DUT 103 to third gate switch 117. Third gate switch 117 may selectively couple the gate node of third DUT 103 to one of gate stress voltage source 111 and multiplexer 170.

A sixth node 176 of socket 104 may couple a drain node of third DUT 103 to third drain switch 107. Third drain switch 107 may selectively couple the drain node of third DUT 103 to one of drain stress voltage source 110 and multiplexer 160.

First measurement circuit 120 may operate in a current mode or a voltage mode. Switch 125 may select current mode or voltage mode. In current mode, current source 122 may force a current and voltage detector 121 may measure a voltage. In voltage mode, voltage source 124 may force a voltage and current detector 123 may measure a current. Measurement outputs of first measurement circuit 120 may be output to a microcontroller, processor or other circuit capable to receive measurement outputs.

Second measurement circuit 130 may operate in a current mode or a voltage mode. Switch 135 may select current mode or voltage mode. In current mode, current source 132 may force a current and voltage detector 131 may measure a voltage. In voltage mode, voltage source 134 may force a voltage and current detector 133 may measure a current. Measurement outputs of second measurement circuit 130 may be output to a microcontroller, processor or other circuit capable to receive measurement outputs.

In operation, first measurement circuit 120 and second measurement circuit 130 may measure one or more parametric data values at one of DUTs 101, 102, 103. First measurement circuit 120 and second measurement circuit 130 may output the one or more parametric values to a microcontroller, processor or other circuit capable to receive parametric value outputs. In this manner, system 100 may enable measurement of parametric values during a reliability testing operation. As described previously, the DUT may be a semiconductor device of greater complexity, in which case the number of measurement circuits may increase accordingly.

In the example illustrated in FIG. 1, first DUT 101 is shown as a single metal-oxide semiconductor field-effect device (MOSFET), but this is not intended to be limiting. First drain switch 105 may be coupled to a node other than a drain node of first DUT 101. First gate switch 115 may be coupled to a node other than a gate node of first DUT 101.

In the example illustrated in FIG. 1, second DUT 102 is shown as a single metal-oxide semiconductor field-effect device (MOSFET), but this is not intended to be limiting. Second drain switch 106 may be coupled to a node other than a drain node of second DUT 102. Second gate switch 116 may be coupled to a node other than a gate node of second DUT 102.

In the example illustrated in FIG. 1, third DUT 103 is shown as a single metal-oxide semiconductor field-effect device (MOSFET), but this is not intended to be limiting. Third drain switch 107 may be coupled to a node other than a drain node of third DUT 103. Third gate switch 117 may be coupled to a node other than a gate node of third DUT 103.

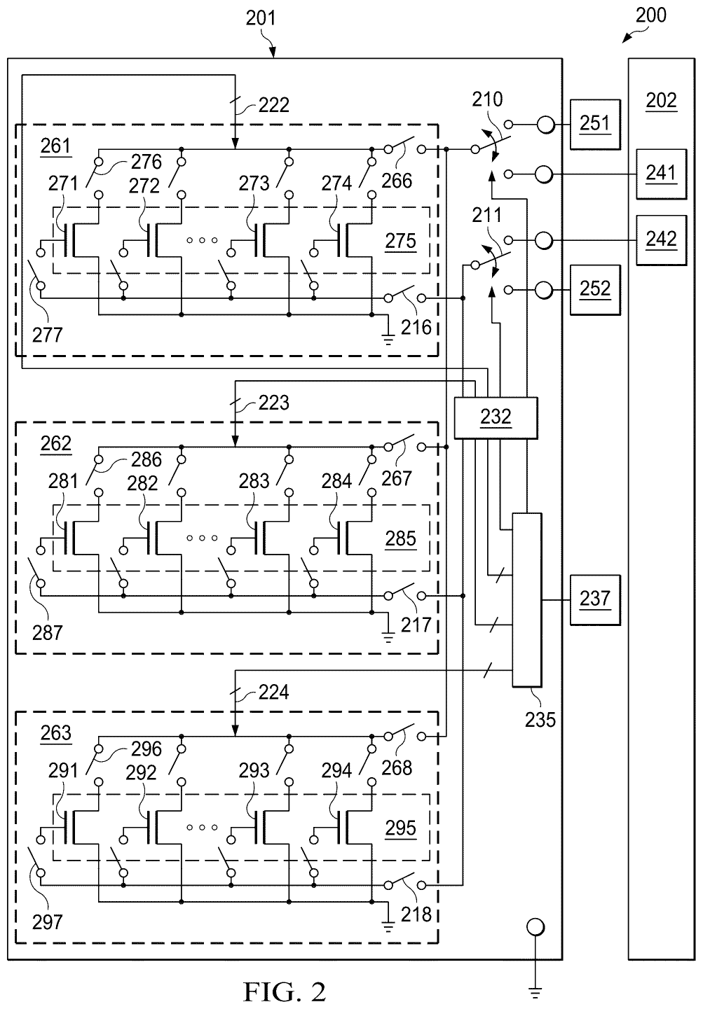

FIG. 2 illustrates another example of a system 200 for monitoring semiconductor device parametric data during a reliability testing operation.

System 200 may include test board 201 and measurement system 202. Measurement system 202 may be a dedicated hardware circuit or may be part of a system-on-a-chip (SoC) including sensors, data converters, processors and other circuits without limitation. Test board 201 may be a PCB or may be another type of board connecting one or more electronic components.

Test board 201 may include one or more DUTs. In the example illustrated in FIG. 2, test board 201 may include DUTs 271, 272, 273, 274, 281, 282, 283, 284, 291, 292, 293, 294. DUTs 271, 272, 273, 274, 281, 282, 283, 284, 291, 292, 293, 294 may be semiconductor devices. DUTs 271, 272, 273, 274, 281, 282, 283, 284, 291, 292, 293, 294 may be single-transistor MOSFET devices as illustrated in FIG. 2, or may be semiconductor devices of greater complexity.

Test board 201 may be comprised of one or more cards. In the example illustrated in FIG. 2, test board 201 may include cards 261, 262, and 263. Cards 261, 262, 263 may be coupled to test board 201 via insertion into a slot, connection via a cable or other electrical connector, or coupled using another type of apparatus for receiving an electrical component. Cards 261, 262, 263 may be printed circuit boards or may be another type of electrical circuit. Cards 261, 262, 263 may be a separate component electrically coupled to test board 201 or may be dedicated region of test board 201.

Card 261 may include DUTs 271, 272, 273 and 274. Socket 275 may receive DUTs 271, 272, 273 and 274 via an electrical connector and socket 275 may be soldered or may be otherwise electrically coupled to card 261. DUTs 271, 272, 273 and 274 may be soldered to socket 275, may be received by a reusable socket or otherwise electrically connected to socket 275. Card 262 may include DUTs 281, 282, 283 and 284. Socket 285 may receive DUTs 281, 282, 283 and 284 via an electrical connector and socket 285 may be soldered or may be otherwise electrically coupled to card 262. DUTs 281, 282, 283 and 284 may be soldered to socket 285, may be received by a reusable socket or otherwise electrically connected to socket 285. Card 263 may include DUTs 291, 292, 293 and 294. Socket 295 may receive DUTs 291, 292, 293 and 294 via an electrical connector and socket 295 may be soldered or may be otherwise electrically coupled to card 263. DUTs 291, 292, 293 and 294 may be soldered to socket 295, may be received by a reusable socket or otherwise electrically connected to socket 295.

Respective DUTs may be located within a thermal control unit and may be attached to a thermocouple such that an ambient temperature may be set for respective DUTs. All DUTs may be tested at a similar temperature settings, or respective DUTs may be tested at different temperature settings.

Respective DUTs may be located within an environmental chamber such that temperature and humidity may be set for respective DUTs. All DUTs may be tested at a similar temperature and humidity setting or respective DUTs may be tested at different temperature and humidity settings.

A thermal control unit or an environmental chamber may control other environmental conditions not limited to temperature and humidity.

In the example illustrated in FIG. 2, socket 275 includes four DUTs, 271, 272, 273, and 274, but this is not intended to be limiting. Socket 275 may include more DUTs or fewer DUTs than the number of DUTs in the example illustrated in FIG. 2.

In the example illustrated in FIG. 2, socket 285 includes four DUTs, 281, 282, 283, and 284, but this is not intended to be limiting. Socket 285 may include more DUTs or fewer DUTs than the number of DUTs in the example illustrated in FIG. 2.

In the example illustrated in FIG. 2, socket 295 includes four DUTs, 291, 292, 293, and 294, but this is not intended to be limiting. Socket 295 may include more DUTs or fewer DUTs than the number of DUTs in the example illustrated in FIG. 2.

Switch driver 232 may generate one or more control signals for relays and switches on test board 201. Switches may include global drain switch 210, global gate switch 211, and gate switches and drain switches in card 261, 262 and 263.

Switch driver 232 may generate switch network controls 222. Switch network controls 222 may drive control signals to gate switches and drain switches coupled to DUTs 271, 272, 273 and 274 to open and close the gate switches and drain switches on card 261 as illustrated in FIG. 2. As one of various examples, switch network controls 222 may include control signals to open and close drain switch 276 and gate switch 277. Individual connections between switch network controls 222 and individual drain switches and gate switches are not shown to improve readability of FIG. 2.

Switch driver 232 may generate switch network controls 223. Switch network controls 223 may drive control signals to gate switches and drain switches coupled to DUTs 281, 282, 283 and 284 to open and close the gate switches and drain switches on card 262 as illustrated in FIG. 2. As one of various examples, switch network controls 223 may include control signals to open and close drain switch 286 and gate switch 287. Individual connections between switch network controls 223 and individual drain switches and gate switches are not shown to improve readability of FIG. 2.

Switch driver 232 may generate switch network controls 224. Switch network controls 224 may drive control signals to gate switches and drain switches coupled to DUTs 291, 292, 293 and 294 to open and close the gate switches and drain switches on card 263 as illustrated in FIG. 2. As one of various examples, switch network controls 224 may include control signals to open and close drain switch 296 and gate switch 297 Individual connections between switch network controls 224 and individual switches are not shown to improve readability of FIG. 2.

Switch driver 232 may generate control signals to open and close high-side switch 266 and low-side switch 216 on card 261. Switch driver 232 may generate switch control signals to open and close high-side switch 267 and low-side switch 217 on card 262. Switch driver 232 may generate switch control signals to open and close high-side switch 268 and low-side switch 218 on card 263.

Communication interface 235 may be coupled to an external controller 237. External controller 237 may be a microcontroller, microprocessor, computer or other communication device. External controller 237 may provide input to communication interface 235 which may provide inputs to switch driver 232 and may provide inputs to switch network controls 224, 223 and 222. External controller 237 may also control first source 251 and second source 252. External controller 237 may also provide control signals to first measurement circuit 241 and second measurement circuit 242 to map the measurements of the DUTs.

Measurement system 202 may include first measurement circuit 241 and second measurement circuit 242. First measurement circuit 241 may include data converters and other circuits used in measuring analog and digital signals. Second measurement circuit 242 may include data converters and other circuits used in measuring analog and digital signals. Circuitry within measurement system 202 may perform one or more calculations based on signals received at first measurement circuit 241 during a first measurement operation. Circuitry within measurement system 202 may perform one or more calculations based on signals received at second measurement circuit 242 during a second measurement operation. As one of various examples, a first voltage may be received at first measurement circuit 241 and a second voltage may be received at second measurement circuit 242. Circuitry within measurement system 202 may compute a differential voltage based on the first voltage and the second voltage. Measurement system 202 may collect multiple samples of data at first measurement circuit 241 and second measurement circuit 242 and may compute parametric data, including but not limited to averages, minimum values, maximum values, and frequency domain transforms. The result of a specific measurement may also be used to determine conditions of a subsequent measurement, including but not limited to a feedback-based measurement.

In operation, first source 251 may drive a predetermined voltage or a predetermined current. Global drain switch 210 may couple the output of first source 251 to card 261, card 262 and card 263. High-side switch 266 may be closed to couple the output of first source 251 to the drain switches on card 261. Switch driver 232 may set switch positions in card 261 via switch network controls 222 to couple the output of first source 251 to at least one of DUT 271, 272, 273, 274. After a predetermined time, second measurement circuit 242 may receive a signal from test board 201. In one of various examples, second measurement circuit 242 may be coupled to a gate node of one of DUT 271, 272, 273, 274 via low-side switch 216 and based on switch network controls 222. Second measurement circuit 242 may measure a voltage or current. In this manner, a node of DUT 271, 272, 273, and 274 may be coupled to second measurement circuit 242 and parametric data values may be collected from DUT 271, 272, 273 and 274 during burn-in testing.

In operation, first source 251 may drive a predetermined voltage or a predetermined current. Global drain switch 210 may couple the output of first source 251 to card 261, card 262 and card 263. High-side switch 267 may be closed to couple the output of first source 251 to the drain switches on card 262. Switch driver 232 may set switch positions in card 262 via switch network controls 223 to couple the output of first source 251 to at least one of DUT 281, 282, 283, 284. After a predetermined time, second measurement circuit 242 may receive a signal from test board 201. In one of various examples, second measurement circuit 242 may be coupled to a gate node of one of DUT 281, 282, 283, 284 via low-side switch 217 and based on switch network controls 223. Second measurement circuit 242 may measure a voltage or current. In this manner, a node of DUT 281, 282, 283, and 284 may be coupled to second measurement circuit 242 and parametric data may be collected from DUT 281, 282, 283 and 284 during burn-in testing.

In operation, first source 251 may drive a predetermined voltage or a predetermined current. Global drain switch 210 may couple the output of first source 251 to card 261, card 262 and card 263. High-side switch 268 may be closed to couple the output of first source 251 to the drain switches on card 263. Switch driver 232 may set switch positions in card 263 via switch network controls 224 to couple the output of first source 251 to at least one of DUT 291, 292, 293, 294. After a predetermined time, second measurement circuit 242 may receive a signal from test board 201. In one of various examples, second measurement circuit 242 may be coupled to a gate node of one of DUT 291, 292, 293, 294 via low-side switch 218 and based on switch network controls 224. Second measurement circuit 242 may measure a voltage or current. In this manner, a node of DUT 291, 292, 293, and 294 may be coupled to second measurement circuit 242 and parametric data may be collected from DUT 291, 292, 293 and 294 during burn-in testing.

In operation, second source 252 may drive a predetermined voltage or a predetermined current. Global gate switch 211 may couple the output of second source 252 to card 261, card 262 and card 263. Low-side switch 216 may be closed to couple the output of second source 252 to the gate switches on card 261. Switch driver 232 may set switch positions in card 261 via switch network controls 222 to couple the output of second source 252 to at least one of DUT 271, 272, 273, 274. After a predetermined time, first measurement circuit 241 may receive a signal from test board 201. In one of various examples, first measurement circuit 241 may be coupled to a drain node of one of DUT 271, 272, 273, 274 via high-side switch 266 and based on switch network controls 222. First measurement circuit 241 may measure a voltage or current. In this manner, parametric data may be collected from DUTs 271, 272, 273 and 274 during burn-in testing.

In operation, second source 252 may drive a predetermined voltage or a predetermined current. Global gate switch 211 may couple the output of second source 252 to card 261, card 262 and card 263. Low-side switch 217 may be closed to couple the output of second source 252 to the gate switches on card 262. Switch driver 232 may set switch positions in card 262 via switch network controls 223 to couple the output of second source 252 to at least one of DUT 281, 282, 283, 284. After a predetermined time, first measurement circuit 241 may receive a signal from test board 201. In one of various examples, first measurement circuit 241 may be coupled to a drain node of one of DUT 281, 282, 283, 284 via high-side switch 267 and based on switch network controls 223. First measurement circuit 241 may measure a voltage or current. In this manner, parametric data may be collected from DUTs 281, 282, 283 and 284 during burn-in testing.

In operation, second source 252 may drive a predetermined voltage or a predetermined current. Global gate switch 211 may couple the output of second source 252 to card 261, card 262 and card 263. Low-side switch 218 may be closed to couple the output of second source 252 to the gate switches on card 263. Switch driver 232 may set switch positions in card 263 via switch network controls 224 to couple the output of second source 252 to at least one of DUT 291, 292, 293, 294. After a predetermined time, first measurement circuit 241 may receive a signal from test board 201. In one of various examples, first measurement circuit 241 may be coupled to a drain node of one of DUT 291, 292, 293, 294 via high-side switch 268 and based on switch network controls 224. First measurement circuit 241 may measure a voltage or current. In this manner, parametric data may be collected from DUTs 291, 292, 293 and 294 during burn-in testing.

As one of various examples, system 200 may measure a current consumption of DUT 271. External controller 237 may provide input to communication interface 235 and may control switch driver 232, switch network controls 222, switch network controls 223 and switch network controls 224. During a first time period, a temperature and humidity may be applied to DUT 271 to initiate a burn-in test, and second source 252 may drive a voltage. Low-side switch 216 may be closed, and switch network controls 222 may be configured to close gate switch 277. In this manner, a voltage may be applied to the gate node of DUT 271. During a second time period, high-side switch 266 may be closed, and switch network controls 222 may be configured to close drain switch 276. Global drain switch 210 may couple high-side switch 266 to first measurement circuit 241. First measurement circuit 241 may measure the current consumption of DUT 271 during a burn-in test.

Parametric data measured by measurement system 202 may be stored in a non-transitory memory. The non-transitory memory may be part of measurement system 202 or may be an external non-transitory memory.

In this manner, a parametric value may be measured during a burn-in test without requiring a DUT to be removed and tested in a separate apparatus.

The previous example illustrates a measurement of a current consumption in DUT 271, but this is not intended to be limiting. System 200 may measure any respective parametric value in any respective DUT.

In one of various examples, system 200 may drive both a gate node and a drain node of one of DUTs 271, 272, 273, 274, 281, 282, 283, 284, 291, 292, 293, 294. In operation, first source 251 may drive a predetermined voltage or a predetermined current. Global drain switch 210 may couple the output of first source 251 to card 261, card 262 and card 263. High-side switch 266 may be closed to couple the output of first source 251 to the drain switches on card 261. Switch driver 232 may set switch positions in card 261 via switch network controls 222 to couple the output of first source 251 to DUT 271. Second source 252 may drive a predetermined voltage or a predetermined current. Global gate switch 211 may couple the output of second source 252 to card 261, 262 and 263. Low-side switch 216 may be closed to couple the output of second source 252 to the gate switches on card 261. Switch driver 232 may set switch positions in card 261 via switch network controls 222 to couple the output of second source 252 to DUT 271. In this manner both a gate voltage and a drain voltage may be applied to DUT 271. The gate voltage and drain voltage may be applied to DUT 271 for a predetermined time. The predetermined time may be specified by a reliability test protocol. At the conclusion of the predetermined time, one or more parametric values may be measured. Global drain switch 210 may be switched to couple first measurement circuit 241 to the drain of DUT 271. First measurement circuit 241 may measure a parametric value at the drain of DUT 271. First measurement circuit 241 may measure a voltage or a current. Global gate switch 211 may be switched to couple second measurement circuit 242 to the gate of DUT 271. Second measurement circuit 242 may measure a parametric value at the gate of DUT 271. Second measurement circuit 242 may measure a voltage or a current. In this manner a voltage or current may be measured at DUT 271 after driving a voltage or current to both the gate node and the drain node of DUT 271.

System 200 may measure parametric data at a single DUT, or may measure parametric data at multiple DUTs in sequence, as part of a reliability testing operation.

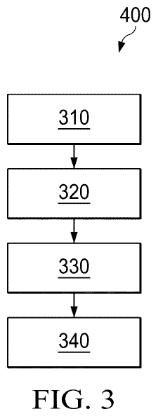

FIG. 3 illustrates a method 300 of monitoring semiconductor device parametric data during a reliability testing operation.

At operation 310, a temperature and a humidity level may be set at a DUT.

At operation 320, a voltage or current may be applied to one or more nodes of the DUT.

At operation 330, one or more nodes of the DUT may be coupled to a measurement unit.

At operation 340, a voltage or current at the one or more nodes of the DUT coupled to a measurement unit may be measured.

1. A device comprising:
a circuit board comprising:
one or more sockets, respective sockets to receive one or more semiconductor devices;
at least one gate switch, a first node of the at least one gate switch coupled to a first node of a respective socket;
at least one drain switch, a first node of the at least one drain switch coupled to a second node of a respective socket;
a high-side switch to selectively couple respective second nodes of the at least one drain switch to a global drain switch, the global drain switch selectively coupled to a first source and a first measurement circuit;
a low-side switch to selectively couple respective second nodes of the one or more gate switches to a global gate switch, the global gate switch selectively coupled to a second source and a second measurement circuit;
a switch driver to generate control signals to the at least one drain switch, the at least one gate switch, the high-side switch, the low-side switch, the global gate switch and the global drain switch; and
wherein the switch driver to configure the at least one drain switch, the at least one gate switch, the high-side switch, the low-side switch, the global gate switch and the global drain switch to couple a signal from the first source to one of the one or more sockets and to measure one or more parametric values at the second measurement circuit and to couple a signal from the second source to one of the one or more sockets and to measure one or more parametric values at the first measurement circuit.

2. The device as claimed in claim 1, respective sockets comprising a thermal control unit to set a temperature at respective received semiconductor devices.

3. The device as claimed in claim 1, respective sockets comprising an environmental chamber to set a level of humidity at respective received semiconductor devices.

4. The device as claimed in claim 1, the switch driver to generate control signals to couple respective first nodes of the one or more sockets to the second measurement circuit in sequence, the second measurement circuit to measure one or more parametric data values during a reliability testing operation.

5. The device as claimed in claim 1, the switch driver to generate control signals to couple respective second nodes of the one or more sockets to the first measurement circuit in sequence, the first measurement circuit to measure one or more parametric data values during a reliability testing operation.

6. The device as claimed in claim 1, the first source to apply a predetermined voltage to the global drain switch, as part of a reliability testing operation.

7. The device as claimed in claim 1, the second source to apply a predetermined voltage to the global gate switch, as part of a reliability testing operation.

8. The device as claimed in claim 1, the first source to apply a predetermined voltage to the global drain switch and the second source to apply a predetermined voltage to the global gate switch, as part of a reliability testing operation.

9. The device as claimed in claim 1, the switch driver to generate control signals to couple respective first nodes of the one or more sockets to the second measurement circuit and the second nodes of the one or more sockets to the first measurement circuit, the first and second measurement circuits to measure one or more parametric data values.

10. A system comprising:
a controller coupled to a circuit board, the circuit board comprising:
one or more cards comprising one or more sockets, respective sockets to receive one or more semiconductor devices;
at least one gate switch, a first node of the at least one gate switch coupled to a first node of a respective socket;
at least one drain switch, a first node of the at least one drain switch coupled to a second node of a respective socket;
a high-side switch to selectively couple respective second nodes of the at least one drain switch to a global drain switch, the global drain switch coupled to a first source and a first measurement circuit;
a low-side switch to selectively couple respective second nodes of the one or more gate switches to a global gate switch, the global gate switch coupled to a second source and a second measurement circuit;
a switch driver to generate control signals to the at least one drain switch, the at least one gate switch, the high-side switch, the low-side switch, the global gate switch and the global drain switch; and
wherein, during a reliability testing operation, the controller to instruct the switch driver to couple the first node of one of the received semiconductor devices to a first measurement circuit and to instruct the first measurement circuit to perform a first measurement operation and the controller to instruct the switch driver to couple a second node of one of the received semiconductor devices to the second measurement circuit and to instruct the second measurement circuit to perform a second measurement operation.

11. The system as claimed in claim 10, the system comprising a non-transitory memory coupled to the controller, wherein the controller to store results of the first measurement operation in the non-transitory memory.

12. The system as claimed in claim 10, the system comprising a non-transitory memory coupled to the controller, wherein the controller to store results of the second measurement operation in the non-transitory memory.

13. The system as claimed in claim 10, the switch driver to generate control signals to couple respective first nodes of the one or more sockets to the second measurement circuit in sequence, the second measurement circuit to measure one or more parametric data values during a reliability testing operation.

14. The system as claimed in claim 10, the switch driver to generate control signals to couple respective second nodes of the one or more sockets to the first measurement circuit in sequence, the first measurement circuit to measure one or more parametric data values during a reliability testing operation.

15. The system as claimed in claim 10, the controller to instruct the first source to apply a predetermined voltage to the global drain switch at a predetermined time, as part of a reliability testing operation.

16. The system as claimed in claim 10, the controller to instruct the second source to apply a predetermined voltage to the global gate switch, as part of a reliability testing operation.

17. A method comprising:
setting an environmental condition at a device under test;
applying a voltage or current to one or more nodes of the device under test;
coupling one or more nodes of the device under test to a measurement unit; and
measuring, at the measurement unit, during a reliability testing operation, one or more parametric data values of the device under test.

18. The method as claimed in claim 17, comprising storing the one or more parametric data values in a non-transitory storage medium.
